(19) United States
(12) Patent Application Publication
(10) Pub. No.: US 2025/0069969 A1
(43) Pub. Date: Feb. 27, 2025

(54) SEMICONDUCTOR PACKAGE INCLUDING PROTECTIVE LAYER WITH FILLERS

(71) Applicant: SAMSUNG ELECTRONICS CO., LTD., Suwon-si (KR)

(72) Inventor: Daehyun KIM, Suwon-si (KR)

(73) Assignee: SAMSUNG ELECTRONICS CO., LTD., Suwon-si (KR)

(21) Appl. No.: 18/627,071

(22) Filed: Apr. 4, 2024

(30) Foreign Application Priority Data
Aug. 23, 2023 (KR) 10-2023-0110515

(51) Int. Cl. H01L 23/29; H01L 23/00; H01L 23/31; H01L 23/498; H01L 25/065

(52) U.S. Cl. CPC H01L 23/295; H01L 23/3128; H01L 23/49816; H01L 23/562; H01L 24/48; H01L 25/0657; H01L 24/32; H01L 24/73; H01L 2224/32145; H01L 2224/32225; H01L 2224/48145; H01L 2224/48227; H01L 2224/73265; H01L 2225/06506; H01L 2225/0651; H01L 2225/06562

(57) ABSTRACT

A semiconductor package includes a substrate including an interconnection, a chip stack including a plurality of semiconductor chips stacked on the substrate, bonding wires electrically coupling the plurality of semiconductor chips to the interconnection, a protective layer on the chip stack and including a first insulating resin and first fillers dispersed in the first insulating resin, a mold at least partially covering the chip stack and the protective layer, the mold including a second insulating resin and second fillers dispersed in the second insulating resin, and connection bumps electrically coupled to the interconnection below the substrate. A first average diameter of the first fillers is smaller than a second average diameter of the second fillers. A first concentration of the first fillers in the first insulating resin is lower than a second concentration of the second fillers in the second insulating resin.

### CROSS-REFERENCE TO RELATED APPLICATIONS

This application claims benefit of priority under 35 U.S.C. § 119 to Korean Patent Application No. 10-2023-0110515, filed on Aug. 23, 2023 in the Korean Intellectual Property Office, the disclosure of which is incorporated by reference herein in its entirety.

### BACKGROUND

### 1. Field

The present disclosure relates generally to a semiconductor package, and more particularly to, a semiconductor package including a protective layer with fillers.

### 2. Description of Related Art

Recently, there has been an increasing demand for increased performance and miniaturization of semiconductor packages installed in electronic devices. Typically, a semiconductor package may be further miniaturized (e.g., reduced form factor) by decreasing a mold gap. However, a decrease in the mold gap may result in a reduced reliability of a plurality of semiconductor chips in the semiconductor package. For example, as a mold gap of a semiconductor package decreases, an uppermost semiconductor chip of a chip stack may become more vulnerable to external forces, and thus, a reliability of the uppermost semiconductor chip may be reduced. Thus, there exists a need for further improvements in semiconductor packaging technology, as the need for miniaturization of semiconductor packages with smaller mold gaps may be constrained by a reliability of an uppermost semiconductor chip from among a plurality of semiconductor chips in the semiconductor packages. Improvements are presented herein. These improvements may also be applicable to other semiconductor technologies.

### SUMMARY

One or more example embodiments of the present disclosure provide a semiconductor package having improved reliability when compared with related semiconductor packages.

According to an aspect of the present disclosure, a semiconductor package includes a substrate including an interconnection, a chip stack including a plurality of semiconductor chips stacked on the substrate, bonding wires electrically coupling the plurality of semiconductor chips to the interconnection, a protective layer on the chip stack and including a first insulating resin and first fillers dispersed in the first insulating resin, a mold at least partially covering the chip stack and the protective layer, the mold including a second insulating resin and second fillers dispersed in the second insulating resin, and connection bumps electrically coupled to the interconnection below the substrate. A first average diameter of the first fillers is smaller than a second average diameter of the second fillers. A first concentration of the first fillers in the first insulating resin is lower than a second concentration of the second fillers in the second insulating resin.

According to an aspect of the present disclosure, a semiconductor package includes a substrate including an interconnection, a chip stack including a plurality of semiconductor chips stacked on the substrate, bonding wires electrically coupling the plurality of semiconductor chips to the interconnection, a protective layer on the chip stack and including first fillers, and a mold at least partially covering the chip stack and the protective layer, the mold including second fillers. The protective layer includes a first portion having a first thickness and a second portion having a second thickness. The second thickness is different from the first thickness.

According to an aspect of the present disclosure, a semiconductor package includes a substrate including an interconnection, a chip stack including a plurality of semiconductor chips stacked on the substrate, bonding wires electrically coupling the plurality of semiconductor chips to the interconnection, a protective layer on the chip stack and including first fillers, and a mold at least partially covering the chip stack and the protective layer, the mold including second fillers. A first concentration of the first fillers in the protective layer is lower than a second concentration of the second fillers in the mold.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description, taken in conjunction with the accompanying drawings, in which:

FIG. 1A is a cross-sectional view of a semiconductor package, according to an example embodiment;

FIG. 1B is a plan view of the semiconductor package of FIG. 1A, according to an example embodiment;

FIG. 1C is a partially enlarged view of region “A” of FIG. 1, according to an example embodiment;

FIG. 2 is a diagram illustrating an indentation strength of a semiconductor package, according to an example embodiment;

FIG. 3 is a diagram illustrating bending properties of a semiconductor package, according to an example embodiment;

FIGS. 4A to 4D are plan views illustrating protective layers, according to example embodiments;

FIG. 5 is a cross-sectional view of a semiconductor package, according to an example embodiment;

FIG. 6 is a cross-sectional view of a semiconductor package, according to an example embodiment; and

FIGS. 7A to 7C are cross-sectional views for illustrating the manufacturing process of the semiconductor package of FIG. 6, according to example embodiments.

### DETAILED DESCRIPTION

Hereinafter, with reference to the accompanying drawings, example embodiments of the present disclosure are described. Unless otherwise specified, in the present disclosure, terms such as “upper portion,” “upper surface,” “lower portion,” “lower surface,” “side surface,” and the like, are based on the drawings, and may actually vary depending on a direction in which the components are arranged.

As used herein, an ordinal number such as “first,” “second,” “third,” and the like may be used as a label of specific elements, steps, directions, and the like to distinguish various elements, steps, and directions from each other. Terms not described using “first,” “second,” and the like, in the present disclosure may be referred to as “first” or “second” in the claims. In addition, a term referenced by a particular ordinal number (e.g., “first” in a claim) may be recited elsewhere by a different ordinal number (e.g., “second” in a description and/or another claim).

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include possible combinations of the items enumerated together in a corresponding one of the phrases. It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second”,∂third” to be used to describe relative positions of elements. The terms “first,” “second”,“third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

As used herein, each of the terms “Sn—Ag—Cu”, and the like may refer to a material made of elements included in each of the terms and is not a chemical formula representing a stoichiometric relationship.

Hereinafter, various embodiments of the present disclosure are described with reference to the accompanying drawings.

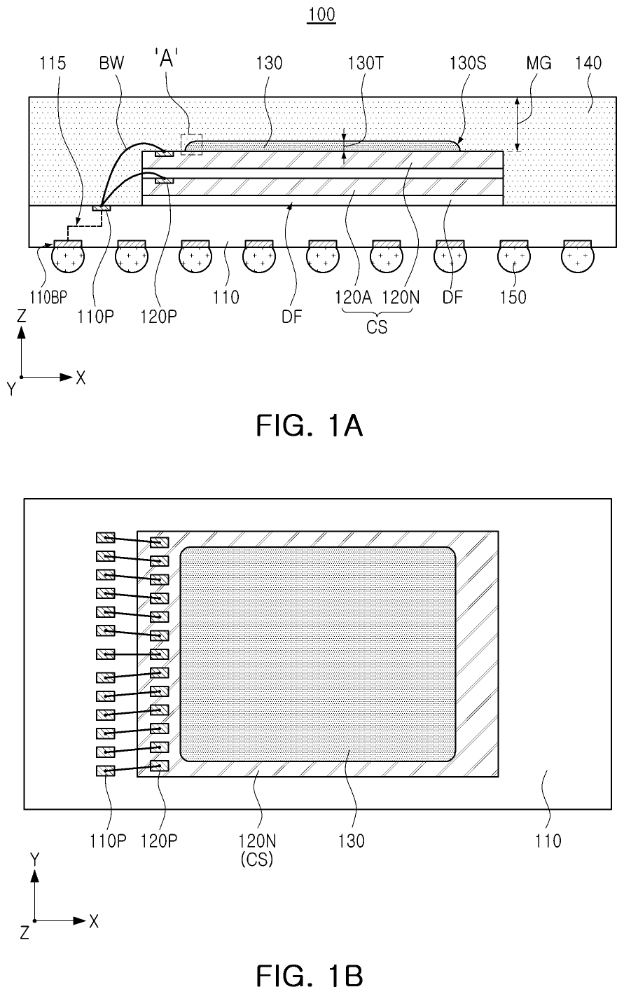

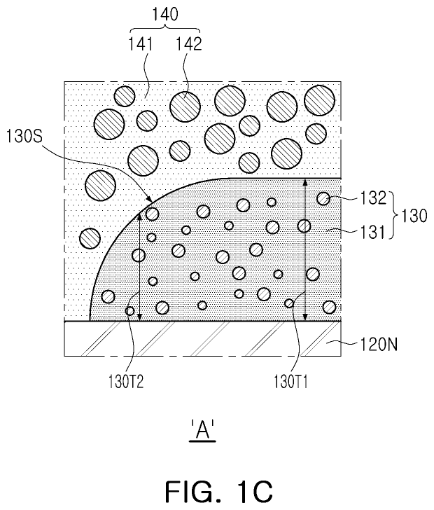

FIG. 1A is a cross-sectional view of a semiconductor package 100, according to an example embodiment. FIG. 1B is a plan view of the semiconductor package 100 of FIG. 1A, according to an example embodiment. FIG. 1C is a partially enlarged view of region “'A” of FIG. 1A, according to an example embodiment.

Referring to FIGS. 1A to 1C, the semiconductor package 100 may include a substrate 110, a plurality of semiconductor chips (e.g., first semiconductor chip 120A and uppermost semiconductor chip 120N, hereinafter generally referred to as “120”, where N is a positive integer greater than zero (0)), a protective layer 130, and a mold 140. According to example embodiments, the semiconductor package 100 may further include connection bumps 150. Although FIG. 1A depicts the plurality of semiconductor chips 120 as having two (2) semiconductor chips, the present disclosure is not limited in this regard. For example, the plurality of semiconductor chips 120 may have three or more semiconductor chips.

The substrate 110 may be and/or may include a semiconductor package substrate such as, but not limited to, a printed circuit board (PCB), a ceramic substrate, a glass substrate, a tape interconnection substrate, and the like. For example, the substrate 110 may be and/or may include a double-sided PCB and/or a multi-layer PCB.

The substrate 110 may include bonding pads 110P, bump pads 110BP, and an interconnection 115 electrically connecting the same. The bonding pads 110P may be disposed on an upper surface of the substrate 110, and the bump pads 110BP may be disposed on a lower surface of the substrate 110. The bonding pads 110P and the bump pads 110BP may include at least one metal from among copper (Cu), aluminum (Al), nickel (Ni), silver (Ag), gold (Au), platinum (Pt), tin (Sn), and lead (Pb), titanium (Ti), chromium (Cr), palladium (Pd), indium (In), zinc (Zn), and carbon (C), and/or an alloy composed of two or metals thereof.

In an example embodiment, connection bumps 150 may be disposed below the bump pads 110BP. The connection bumps 150 may be electrically connected to the plurality of semiconductor chips 120 through the interconnection 115. The connection bumps 150 may include, for example, tin (Sn) and/or an alloy containing tin (Sn) (e.g., Sn—Ag—Cu). The connection bumps 150 may be electrically connected to external devices such as, but not limited to, a module substrate, a system board, and the like.

The plurality of semiconductor chips 120 may be stacked in a vertical direction (Z-direction) on the substrate 110. The plurality of semiconductor chips 120 may be electrically connected to bonding pads 110P of the substrate 110 through bonding wires BW. For example, the bonding wires BW may electrically connect the connection pads 120P of the plurality of semiconductor chips 120 to the bonding pads 110P of the substrate 110. The bonding wires BW may include, but not be limited to, gold (Au), silver (Ag), lead (Pb), aluminum (Al), copper (Cu), and/or an alloy composed of two or metals thereof. However, the present disclosure not limited thereto. The connection pads 120P may include, but not be limited to, any one of copper (Cu), nickel (Ni), titanium (Ti), and aluminum (Al) or an alloy composed of two or metals thereof. The plurality of semiconductor chips 120 may be attached to the substrate 110 and/or to each other using an adhesive film DF.

The plurality of semiconductor chips 120 may form a chip stack CS connected to the interconnection 115 of the substrate 110. The plurality of semiconductor chips 120 may be and/or may include a flash memory semiconductor chip, a non-volatile memory semiconductor chip (e.g., a phase-change random access memory (PRAM), a magneto-resistive random access memory (MRAM), a ferroelectric random access memory (FeRAM), a resistive random access memory (RRAM), and the like), and/or a volatile memory semiconductor chip (e.g., a dynamic random access memory (DRAM), a static random access memory (SRAM), and the like). In an example embodiment, the plurality of semiconductor chips 120 may include the same type of semiconductor chip. In an optional or additional example embodiment, the plurality of semiconductor chips 120 may include different types of semiconductor chips. That is, the present disclosure is not limited in this regard.

A protective layer 130 may be disposed on the chip stack CS. The protective layer 130 may include a first insulating resin 131 and first fillers 132. The first insulating resin 131 may include, for example, a thermosetting resin such as, but not limited to, an epoxy resin. The first fillers 132 may be and/or may include inorganic fillers dispersed in the first insulating resin 131. For example, the first fillers 132 may be and/or may include crystalline silica particles having a diameter ranging from about 1 micrometer (μm) to about 20 μm.

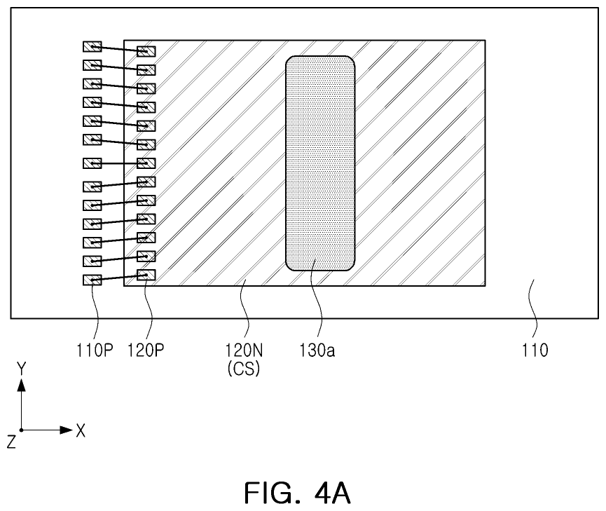

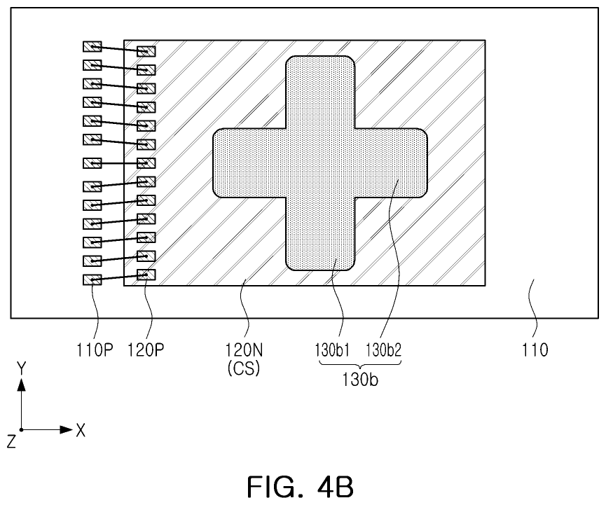

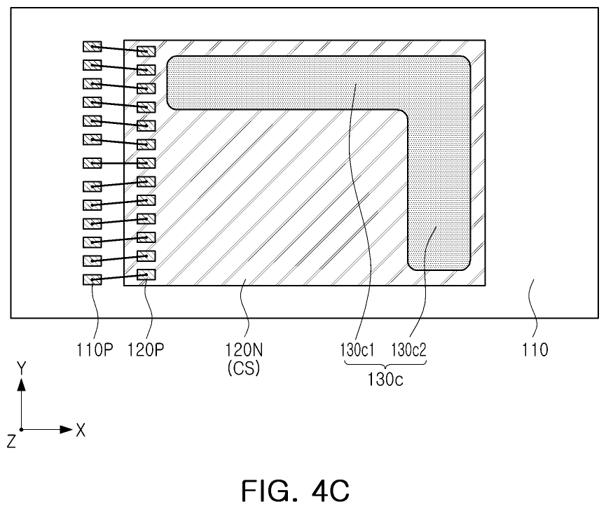

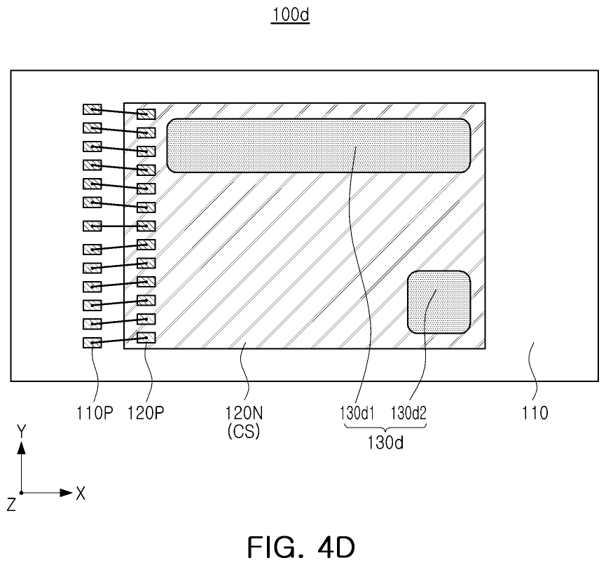

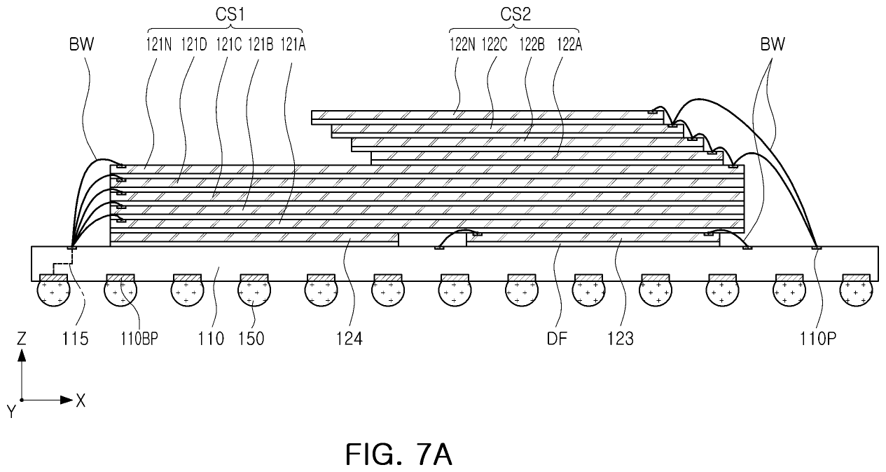

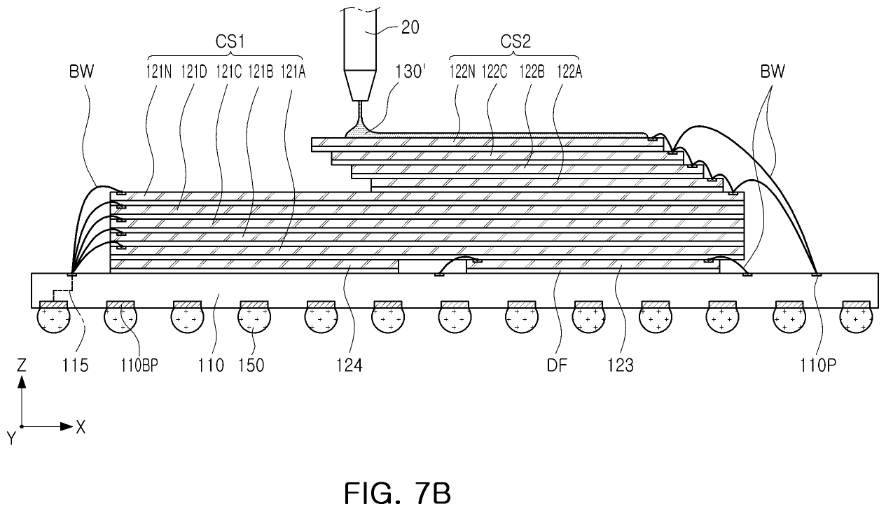

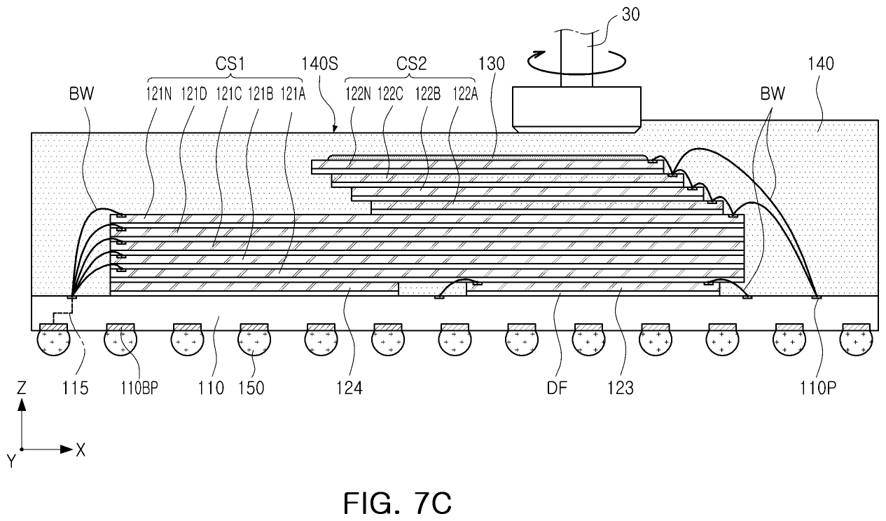

The protective layer 130 may be formed by applying and curing a paste mixed with the first insulating resin 131 and the first fillers 132 on an uppermost semiconductor chip 120N (see FIG. 7B). The protective layer 130 may be formed to cover at least a portion of an upper surface of the uppermost semiconductor chip 120N from among the plurality of semiconductor chips 120. The protective layer 130 may be formed in various shapes on the upper surface of the uppermost semiconductor chip 120N (see FIGS. 4A to 4D). A surface 130S of the protective layer 130 in contact with the mold 140 may include a curved surface. A thickness 130T of the protective layer 130 may be reduced toward an edge of the protective layer 130. For example, the protective layer 130 may include a first portion having a first thickness 130T1 and a second portion having a second thickness 130T2, different from the first thickness 130T1. The second portion of the protective layer 130 may be located closer to the edge of the protective layer 130 than the first portion, and the second thickness 130T2 may be less (e.g., thinner) than the first thickness 130T1.

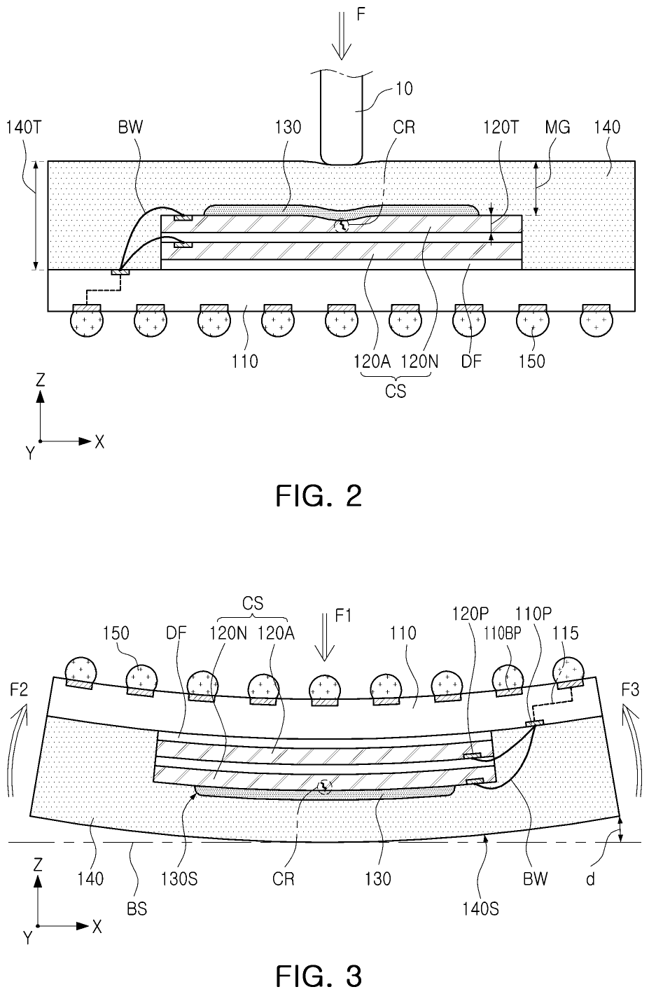

According to example embodiments, the first fillers 132 included in the protective layer 130 may have a lower concentration than second fillers 142 included in the mold 140, thereby protecting the uppermost semiconductor chip 120N and potentially improving indentation strength of the package 100, when compared to related semiconductor packages, as described with reference to FIG. 2.

In an example embodiment, the first concentration of the first fillers 132 may be lower than a second concentration of the second fillers 142. In some example embodiments, the first concentration of the first fillers 132 may be less than or equal to about 70 percent by weight (wt %). For example, the first concentration of the first fillers 132 may range from about 50 wt % to about 70 wt %. As another example, the first concentration of the first fillers 132 may range from about 40 wt % to about 70 wt %. As yet another example, the first concentration of the first fillers 132 may range from about 40 wt % to about 60 wt %. The second concentration of the second fillers 142 may range from about 80 wt % to about 90 wt %, however the present disclosure is not limited thereto. When the first concentration of the first fillers 132 is less than about 50 wt %, a moisture absorption rate of the protective layer 130 may increase and a strength improvement effect may be reduced. When the first concentration of the first fillers 132 exceeds about 70 wt %, an improvement in the indentation strength may be reduced.

According to example embodiments, the first fillers 132 included in the protective layer 130 may have a smaller size than the second fillers 142 included in the mold 140, thereby protecting the uppermost semiconductor chip 120N and improving bending properties of the semiconductor package 100, when compared to related semiconductor packages, as described with reference to FIG. 3.

A maximum diameter of the first fillers 132 may be less than or equal to about 20 μm. For example, a diameter of the first fillers 132 may range from about 1 μm to about 20 μm, however, the present disclosure is not limited thereto. When the diameter of the first fillers 132 is less than about 1 μm or exceeds about 20 μm, an improvement in bending properties may be reduced. In an example embodiment, the maximum diameter of the first fillers 132 may be smaller than the maximum diameter of the second fillers 142. For example, the maximum diameter of the first fillers 132 may be less than or equal to about 20 μm, and the maximum diameter of the second fillers 142 may be greater than or equal to about 40 μm.

A first average diameter of the first fillers 132 may be smaller than a second average diameter of the second fillers 142. For example, the first average diameter may range from about 1 μm to about 10 μm, and the second average diameter may range from about 10 μm to about 30 μm, however, the present disclosure is not limited thereto.

A mold 140 may cover the chip stack CS and the protective layer 130. The mold 140 may include a second insulating resin 141 and the second fillers 142. The second insulating resin 141 may include, for example, a thermosetting resin such as, but not limited to, an epoxy resin. The second fillers 142 may be and/or may include inorganic fillers dispersed in the second insulating resin 141. For example, the second fillers 142 may be and/or may include crystalline silica particles having a diameter ranging from about 1 μm to about 60 μm. The mold 140 may protect the chip stack CS from external environments such as, but not limited to, physical shock and/or moisture. The mold 140 may be formed, for example, by curing epoxy molding compound (EMC).

The protective layer 130 may include the first fillers 132 having the size and concentration described above, thereby potentially improving the reliability of the miniaturized and thinned semiconductor package 100, when compared to related semiconductor packages. For example, the protective layer 130 may improve indentation strength and bending properties of the semiconductor package 100 having an interval (e.g., distance) between the uppermost semiconductor chip 120N from among the plurality of semiconductor chips 120 and an upper surface of the mold 140 less than or equal to about 140 μm.

Hereinafter, with reference to FIGS. 2 and 3, an indentation strength and bending properties of example embodiments are described.

FIG. 2 is a diagram illustrating an indentation strength of a semiconductor package, according to an example embodiment. FIG. 2 schematically illustrates a method of evaluating an indentation strength, according to example embodiments.

As used herein, indentation strength may refer to a value obtained by measuring a maximum force before a crack CR occurs in an uppermost semiconductor chip 120N from among the plurality of semiconductor chips 120 with respect to a force F with which an indentation evaluation tool 10 presses an upper portion of the mold 140 covering the protective layer 130.

Table 1 illustrates indentation strength values of first to fourth examples according to a concentration of the first fillers 132. In the first to fourth examples, a maximum diameter (e.g., about 20 μm) of the first fillers 132, a thickness 140T (e.g., about 590 μm) of the mold 140, a mold gap MG (e.g., about 140 μm), and a thickness 120T (e.g., about 60 μm), of the uppermost semiconductor chip 120N may be set to substantially similar and/or the same values.

TABLE 1
Indentation Strengths

| | First | Second | Third | Fourth |
|---|---|---|---|---|
| Classification | Example | Example | Example | Example |
| Content of First Filler | 88 | 86 | 84 | 82 |
| (wt %) | | | | |
| Coefficient of Expansion | 22.7 | 20.2 | 18.3 | 16.8 |
| (25° C., GPa) | | | | |
| Indentation Strength (N) | 45.4 | 46.5 | 48.6 | 48.9 |

Referring to Table 1, it may be understood that as a concentration of the first fillers 132 (in units of wt %) decreases, a coefficient of expansion (in units of gigaPascal (GPa) at 25° C.) may decrease and an indentation strength (in units of newtons (N)) may increase. For example, according to example embodiments, a semiconductor package 100 may have an indentation strength greater than or equal to about 40 N under the above-described conditions.

FIG. 3 is a diagram illustrating bending properties of a semiconductor package, according to an example embodiment. FIG. 3 schematically illustrates an evaluation method of bending properties, according to example embodiments.

Referring to FIG. 3, as used herein, bending properties may be refer to a value obtained by measuring maximum displacement (d) from a reference line BS before a crack CR occurs in an uppermost semiconductor chip 120N from among the plurality of semiconductor chips 120 with respect to force F (e.g., a three-point bending force that may include a first bending force F1, a second bending force F2, and a third bending force F3) bending the semiconductor package into a “U” shape so that the chip stack CS may face outwardly.

Table 2 illustrates bending properties of a fifth example and a comparative example, according to a size of the first fillers 132. In the fifth example and the comparative example, a concentration of the first fillers 132 (e.g., about 88 wt %), a thickness 140T of the mold 140 (e.g., about 590 μm), a mold gap MG (e.g., about 140 μm), and a thickness 120T of the uppermost semiconductor chip 120N (e.g., about 60 μm) may be set to substantially similar and/or the same values.

TABLE 2
Bending Properties

| | Comparative | Fifth |
|---|---|---|
| Classification | Example | Example |
| Diameter of First Filler (maximum/average) | 55/14 | 20/8 |
| (μm) | | |
| Bending Properties (μm) | 2953 | 3773 |

Referring to Table 2 shown above, an average diameter of the first fillers of the comparative example may be about 14 μm, and an average diameter of the first fillers of the fifth example may be about 8 μm. Thus, it may be understood that the bending properties of the fifth example in which the first fillers 132 are smaller may be improved when compared with the bending properties of the comparative example. For example, according to example embodiments, a semiconductor package 100 may have a bending property greater than or equal to about 3000 μm under the above-described conditions.

FIGS. 4A to 4D are plan views illustrating a protective layer, according to example embodiments.

Referring to FIG. 4A, a semiconductor package 100a may include a protective layer 130a extending from a central portion of an uppermost semiconductor chip 120N in a first direction (e.g., Y-direction). For example, the protective layer 130a may extend in a direction parallel to an arrangement direction of the connection pads 120P. In some embodiments, the protective layer 130a may be formed to have an area less than or equal to about 50% of a planar area of the uppermost semiconductor chip 120N. However, the present disclosure is not limited thereto, and the area of the protective layer 130a may vary (e.g., may be smaller or larger than about 50%) in relation to the planar area of the uppermost semiconductor chip 120N.

Referring to FIG. 4B, a semiconductor package 100b may include a protective layer 130b extending from a central portion of an uppermost semiconductor chip 120N in a first direction (e.g., Y-direction) and a second direction (e.g., X-direction). For example, the protective layer 130b may include a first portion 130b1 extending in a first direction (e.g., Y-direction) and a second portion 130b2 extending in a second direction (e.g., X-direction). The first portion 130b1 and the second portion 130b2 may cross each other, however the present disclosure is not limited thereto. In an example embodiment, the protective layer 130b may be formed to have an area greater than or equal to about 50% of a planar area of the uppermost semiconductor chip 120N, however the present disclosure is not limited thereto.

Referring to FIG. 4C, a semiconductor package 100c may include a protective layer 130c extending from an edge of an uppermost semiconductor chip 120N. For example, the protective layer 130c may include a first portion 130cl extending in a first direction (e.g., X-direction) and a second portion 130c2 extending in a second direction (e.g., Y-direction). The first portion 130cl and the second portion 130c2 may intersect each other, however the present disclosure is not limited thereto.

Referring to FIG. 4D, a semiconductor package 100d may include protective layers 130d spaced apart from each other on an upper surface of an uppermost semiconductor chip 120N. For example, the protective layers 130d may include a first portion 130d1 located in a first region of the upper surface of the uppermost semiconductor chip 120N and a second portion 130d2 located in a second region of the upper surface of the uppermost semiconductor chip 120N.

According to example embodiments, the protective layer 130 may be formed into various shapes through a dispensing process. Thereby, the protective layer 130 may be formed only in some regions of the uppermost semiconductor chip 120N that may need reinforcement.

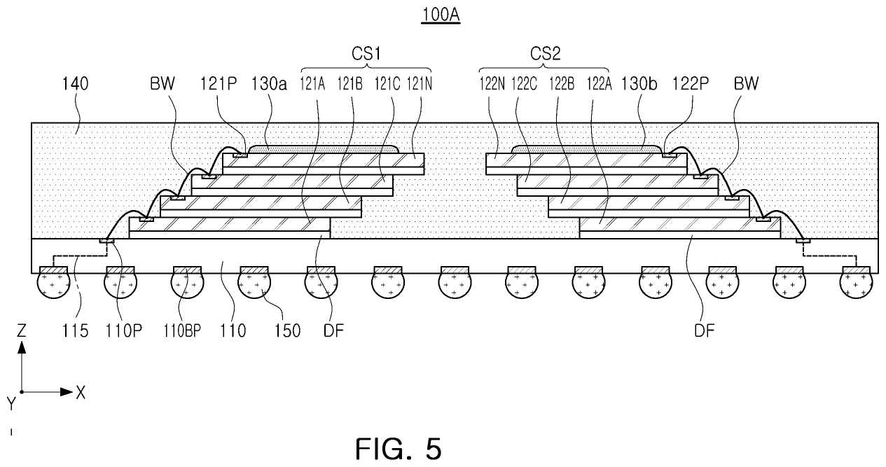

FIG. 5 is a cross-sectional view of a semiconductor package 100A, according to one or more example embodiments.

Referring to FIG. 5, the semiconductor package 100A may include and/or may be similar in many respects to the semiconductor packages described with reference to FIGS. 1A to 4D, and may include additional features not mentioned above. For example, the semiconductor package 100A of FIG. 5 may include a plurality of chip stacks (e.g., a first chip stack CS1 and a second chip stack CS2). As another example, the semiconductor package 100A may further include a plurality of protective layers (e.g., a first protective layer 130a and a second protective layer 130b) disposed on the plurality of chip stacks CS1 and CS2. In some embodiments, the semiconductor package 100A may have the first or second protective layer 130a or 130b disposed on only a portion of the plurality of chip stacks CS1 and CS2 . . . . Although FIG. 5 illustrates the plurality of chip stacks CS1 and CS2 as being spaced apart in a horizontal direction (X-direction) and disposed on the substrate 110 in an “A” shape, the present disclosure is not limited in this regard. For example, the plurality of chip stacks CS1 and CS2 may be disposed thereon in a “V” shape. The plurality of chip stacks CS1 and CS2 may include memory chips of the same type, however the present disclosure is not limited thereto. For example, the plurality of chip stacks CS1 and CS2 may include memory chips of the different types. In an example embodiment, the semiconductor package 100A may further include a controller chip, a buffer chip, and the like, on at least one chip stack of the plurality of chip stacks CS1 and CS2.

The first chip stack CS1 may include a plurality of first semiconductor chips 121 (e.g., a first semiconductor chip 121A, a second semiconductor chip 121B, a third semiconductor chip 121C, and an uppermost first semiconductor chip 121N, hereinafter generally referred to as “121”) that may be vertically stacked. Each of the plurality of first semiconductor chips 121 may include first connection pads 121P connected to bonding pads 110P of the substrate 110 through bonding wires BW. The plurality of first semiconductor chips 121 may be stacked to be offset in a horizontal direction (e.g., X-direction) so that each of the first connection pad 121P may exposed in a vertical direction (Z-direction), however the present disclosure is not limited thereto. A first protective layer 130a may be disposed on the uppermost first semiconductor chip 121N from among the plurality of first semiconductor chips 121.

The second chip stack CS2 may include a plurality of second semiconductor chips 122 (e.g., a first semiconductor chip 122A, a second semiconductor chip 122B, a third semiconductor chip 122C, and an uppermost second semiconductor chip 122N, hereinafter generally referred to as “122”) that may be vertically stacked. Each of the plurality of second semiconductor chips 122 may include second connection pads 122P connected to bonding pads 110P of the substrate 110 through bonding wires BW. The plurality of second semiconductor chips 122 may be stacked to be offset in the horizontal direction (e.g., X-direction) so that each of the second connection pads 122P may be exposed in the vertical direction (Z-direction), however the present disclosure is not limited thereto. A second protective layer 130b may be disposed on the uppermost second semiconductor chip 122N from among the plurality of second semiconductor chips 122.

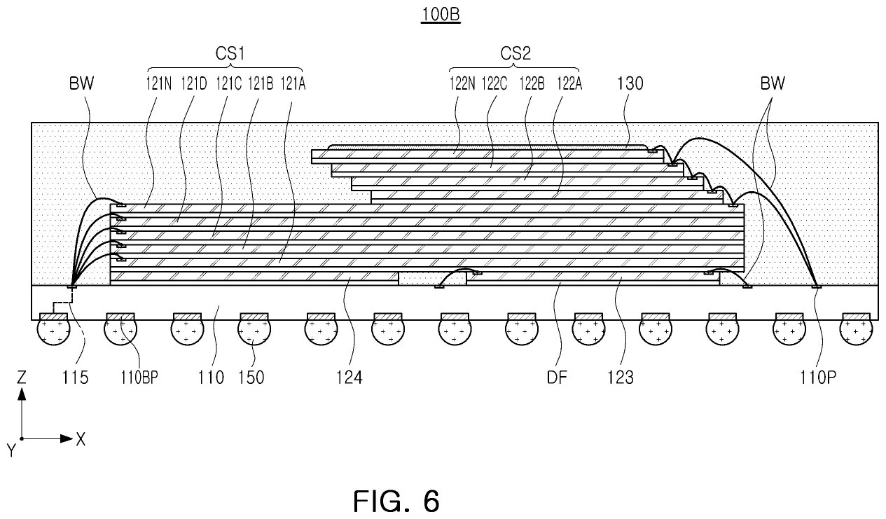

FIG. 6 is a cross-sectional view of a semiconductor package 100B, according to an example embodiment.

Referring to FIG. 6, the semiconductor package 100B may include and/or may be similar in many respects to the semiconductor packages described with reference to FIGS. 1A to 5, and may include additional features not mentioned above. For example, the semiconductor package 100B of FIG. 6 may include a plurality of chip stacks (e.g., a first chip stack CS1 and a second chip stack CS2), which may be vertically stacked. As another example, the semiconductor package 100B may further include a protective layer 130 disposed on the uppermost chip stack CS2 from among the plurality of chip stacks CS1 and CS2. The plurality of chip stacks CS1 and CS2 may include the first chip stack CS1 and the second chip stack CS2 on the first chip stack CS1. The plurality of chip stacks CS1 and CS2 may include different types of memory chips, however the present disclosure is not limited thereto. For example, the first chip stack CS1 may include a DRAM chip, and the second chip stack CS2 may include a flash memory chip. As example, the plurality of chip stacks CS1 and CS2 may include memory chips of the same type.

The first chip stack CS1 may include a plurality of first semiconductor chips 121 (e.g., a first semiconductor chip 121A, a second semiconductor chip 121B, a third semiconductor chip 121C, a fourth semiconductor chip 121D and an uppermost first semiconductor chip 121N, hereinafter generally referred to as “121”) that may be vertically stacked. Each of the plurality of first semiconductor chips 121 may include first connection pads 121P connected to bonding pads 110P of the substrate 110 through bonding wires BW. The plurality of first semiconductor chips 121 may be aligned and stacked in a vertical direction (e.g., Z-direction) so that each of the first connection pads 121P may overlap in the vertical direction (Z-direction), however the present disclosure is not limited thereto.

The second chip stack CS2 may include a plurality of second semiconductor chips 122 (e.g., a first semiconductor chip 122A, a second semiconductor chip 122B, a third semiconductor chip 122C, and an uppermost second semiconductor chip 122N, hereinafter generally referred to as “122”) that may be vertically stacked. Each of the plurality of second semiconductor chips 122 may include second connection pads 122P connected to bonding pads 110P of the substrate 110 through bonding wires BW. The plurality of second semiconductor chips 122 may be stacked to be offset in a horizontal direction (e.g., X-direction) so that each of the second connection pads 122P may be exposed in the vertical direction (Z-direction), however the present disclosure is not limited thereto. A protective layer 130 may be disposed on the uppermost second semiconductor chip 122N from among the plurality of second semiconductor chips 122. In an example embodiment, the protective layer 130 may be formed only on an upper surface of the semiconductor chip located on a highest level, for example, the uppermost second semiconductor chip 122N.

The semiconductor package 100B may further include a controller chip 123 for the first chip stack CS1 and the second chip stack CS2. The controller chip 123 may be disposed below the first chip stack CS1, however the present disclosure is not limited thereto. The controller chip 123 may be electrically connected to the first chip stack CS1 and the second chip stack CS2 through the bonding wire BW and the interconnection 115 of the substrate 110. The controller chip 123 may be and/or may include a memory controller configured to determine a data processing order of the first chip stack CS1 and the second chip stack CS2, and/or configured to prevent errors and/or bad sectors on the semiconductor chips of the plurality of chip stacks CS1 and CS2.

The semiconductor package 100B may further include a spacer 124 to support the first chip stack CS1 and the second chip stack CS2. The spacer 124 may be disposed on one side of the controller chip 123, to support the first chip stack CS1. The spacer 124 may be and/or may include a silicon dummy that may be electrically insulated from the first chip stack CS1 and the second chip stack CS2, however the present disclosure is not limited thereto.

FIGS. 7A to 7C are cross-sectional views for illustrating a manufacturing process of the semiconductor package 100B of FIG. 6, according to example embodiments.

Referring to FIG. 7A, a first chip stack CS1 and a second chip stack CS2 may be formed on the substrate 110. The first chip stack CS1 may be formed by attaching a plurality of first semiconductor chips (e.g., a first semiconductor chip 121A, a second semiconductor chip 121B, a third semiconductor chip 121C, a fourth semiconductor chip 121D and an uppermost first semiconductor chip 121N, hereinafter generally referred to as “121”) to each other using adhesive films DF. The second chip stack CS2 may be formed by attaching a plurality of second semiconductor chips (e.g., a first semiconductor chip 122A, a second semiconductor chip 122B, a third semiconductor chip 122C, and an uppermost second semiconductor chip 122N, hereinafter generally referred to as “122”) to each other using adhesive films DF. The first chip stack CS1 may be disposed on a controller chip 123 and a dummy chip 124. The controller chip 123, the first chip stack CS1, and the second chip stack CS2 may be electrically connected to the interconnection 115 of the substrate 110 through a wire bonding process.

Referring to FIG. 7B, a paste 130′ may be applied on an uppermost semiconductor chip (e.g., the uppermost second semiconductor chip 122N) using a dispenser 20. The paste 130′ may include the first insulating resin 131 and first fillers 132 dispersed therein, as described with reference to FIGS. 1A to 1C. A protective layer 130 may be formed by curing the paste 130′ applied on the uppermost second semiconductor chip 122N.

Referring to FIG. 7C, a mold 140 may be formed on the substrate 110. An upper surface 140S of the mold 140 may be flattened by a grinder 30. The semiconductor package 100 may have improved indentation strength and bending properties, when compared to a related semiconductor package, and which may be provided by a protective layer 130 formed on the uppermost second semiconductor chip 122N. Accordingly, the mold 140 may be ground thinner, and a miniaturized and thinner semiconductor package may be implemented, when compared to the related semiconductor package.

According to example embodiments of the present disclosure, a semiconductor package having a potentially improved reliability may be provided by introducing a protective layer on an uppermost semiconductor chip.

The various effects and/or advantages of the present disclosure may not be limited to the above description, and may be more apparent in the course of describing the embodiments of the present disclosure. While example embodiments have been shown and described above, it may be apparent to those skilled in the art that modifications and variations may be made without departing from the scope of the present disclosure, as defined by the appended claims.

What is claimed is:

1. A semiconductor package, comprising:
a substrate comprising an interconnection;
a chip stack comprising a plurality of semiconductor chips stacked on the substrate;
bonding wires electrically coupling the plurality of semiconductor chips to the interconnection;
a protective layer on the chip stack and comprising a first insulating resin and first fillers dispersed in the first insulating resin;
a mold at least partially covering the chip stack and the protective layer, the mold comprising a second insulating resin and second fillers dispersed in the second insulating resin; and
connection bumps electrically coupled to the interconnection below the substrate,
wherein a first average diameter of the first fillers is smaller than a second average diameter of the second fillers, and
wherein a first concentration of the first fillers in the first insulating resin is lower than a second concentration of the second fillers in the second insulating resin.

2. The semiconductor package of claim 1, wherein the first average diameter ranges from about 1 micrometer (μm) to about 10 μm, and
wherein the second average diameter ranges from about 10 μm to about 30 μm.

3. The semiconductor package of claim 1, wherein a first maximum diameter of the first fillers is less than or equal to about 20 micrometers (μm), and
wherein a second maximum diameter of the second fillers is greater than or equal to about 40 μm.

4. The semiconductor package of claim 1, wherein the first concentration ranges from about 50 percent by weight (wt %) to about 70 wt %, and
wherein the second concentration ranges from about 80 wt % to about 90 wt %.

5. The semiconductor package of claim 1, wherein the protective layer comprises a first surface in contact with the mold, and
wherein the first surface comprises a curved surface.

6. The semiconductor package of claim 1, wherein a thickness of the protective layer is reduced toward an edge of the protective layer.

7. The semiconductor package of claim 1, wherein the protective layer covers at least a portion of an upper surface of an uppermost semiconductor chip from among the plurality of semiconductor chips.

8. The semiconductor package of claim 1, wherein the first insulating resin and the second insulating resin comprise a thermosetting resin.

9. The semiconductor package of claim 1, wherein the first fillers and the second fillers comprise an inorganic filler.

10. The semiconductor package of claim 9, wherein the first fillers and the second fillers comprise crystalline silica.

11. The semiconductor package of claim 1, wherein a distance between an uppermost semiconductor chip from among the plurality of semiconductor chips and an upper surface of the mold is less than or equal to about 140 micrometers (μm).

12. The semiconductor package of claim 1, wherein an indentation strength of the semiconductor package is greater than or equal to about 40 newtons (N).

13. The semiconductor package of claim 12, wherein the indentation strength is obtained by measuring a maximum force before a crack occurs in an uppermost semiconductor chip from among the plurality of semiconductor chips with respect to a force pressing on an upper portion of the mold at least partially covering the protective layer.

14. The semiconductor package of claim 1, wherein a bending property of the semiconductor package is greater than or equal to about 3000 micrometer (μm).

15. The semiconductor package of claim 14, wherein the bending property is obtained by measuring a maximum displacement before a crack occurs in an uppermost semiconductor chip from among the plurality of semiconductor chips with respect to a force bending the semiconductor package into a “U” shape so that the chip stack faces outwardly.

16. A semiconductor package, comprising:
a substrate comprising an interconnection;
a chip stack comprising a plurality of semiconductor chips stacked on the substrate;
bonding wires electrically coupling the plurality of semiconductor chips to the interconnection;
a protective layer on the chip stack and comprising first fillers; and
a mold at least partially covering the chip stack and the protective layer, the mold comprising second fillers,
wherein the protective layer comprises a first portion having a first thickness and a second portion having a second thickness, the second thickness being different from the first thickness.

17. The semiconductor package of claim 16, wherein the second portion of the protective layer is located closer to an edge of the protective layer than the first portion, and
wherein the second thickness is smaller than the first thickness.

18. A semiconductor package, comprising:
a substrate comprising an interconnection;
a chip stack comprising a plurality of semiconductor chips stacked on the substrate;
bonding wires electrically coupling the plurality of semiconductor chips to the interconnection;
a protective layer on the chip stack and comprising first fillers; and
a mold at least partially covering the chip stack and the protective layer, the mold comprising second fillers,
wherein a first concentration of the first fillers in the protective layer is lower than a second concentration of the second fillers in the mold.

19. The semiconductor package of claim 18, wherein the first concentration is less than or equal to about 70 percent by weight (wt %).

20. The semiconductor package of claim 18, wherein a maximum diameter of the first fillers is less than or equal to about 20 micrometer (μm).
